(19) United States
(12) Patent Application Publication
(10) Pub. No.: US 2009/0214757 A1
(43) Pub. Date: Aug. 27, 2009

(54) GLUING UNIT FOR AN END EDGE OF A LOG

(75) Inventor: Giovanni GAMBINI, Pisa (IT)

Correspondence Address: LUCAS & MERCANTI, LLP, 475 PARK AVENUE SOUTH, 15TH FLOOR, NEW YORK, NY, 10016, US

(73) Assignee: GAMBINI INTERNATIONAL S.A., Luxembourg (LU)

(21) Appl. No.: 12/391,639

(22) Filed: Feb. 24, 2009

(30) Foreign Application Priority Data
Feb. 26, 2008 (IT) MI2008A000308

(51) Int. Cl. C23C 16/52; C23C 16/54

(52) U.S. Cl. 427/8; 118/50

(57) ABSTRACT

A gluing unit for an end edge of a log and un method implementable in a machine for making logs, wherein the logs (14), which come from a rereeling machine, are fed towards a gluing unit (11) comprising in succession a lower unwinding roller (16), and an upper feeder belt (17) and, immediately downstream of the unwinding roller (16) at least two sections of sloped surface (21, 23), of pre-selected length, followed by a suction roller with vacuum, positioned above which is an upper roller (25), and then a glue dispenser (27), provided above the unwinding roller (16) being an element (19) for blowing a final edge of the log (14) and beneath a photocell (20) for detecting the final edge (21), provided for being surface (34) for evacuating the glued log, provided for being a timing unit (22) for positioning the free end according to an angle (α) depending on the diameter of the log and the pre-selected length of the sloped surface section (21, 23) in such a manner that the log thus located is positioned on the suction roller with its free end of the final edge thereof arranged at the zone of contact with the suction roller.

### CROSS-REFERENCE TO RELATED APPLICATIONS

This application claims the benefit of priority from Italian Paten Application No. M12008A000308, filed Feb. 26, 2008, the contents of which are incorporated herein by reference.

### FIELD OF THE INVENTION

The present invention regards an improved gluing unit for an end edge log. In order to make rolls of toilet paper, paper for domestic use and the like, referred to as “log”, distributing or positioning glue in various manners both on an end edge of the formed single log and on a portion of the roll making up the log to obtain a stable mutual constraint of the finished log, after obtaining the winding of the paper, is currently known.

As a matter of fact, the glue is used for integrally joining—to each other—the final edge and the remaining part of the winding which can be cut into many small rolls, of the desired limited dimension, thus obtaining many finished rolls.

### BACKGROUND OF THE INVENTION

Currently, this application of glue is performed either through spray gluing substance dispensers or by passing the end edge or the roll over a slot at which overflowing glue is supplied, after the end edge has been unwound by a portion from the rest of the winding.

Though operating excellently, these known gluing units may not allow supplying and distributing the glue in a uniform manner and accurately at the desired position.

As a matter of fact, by using spray gluing substance dispensers, the distribution of the glue occurring through the abovementioned dispensers, such distribution is not always continuous and straight and it can lead to applying the glue even in unwanted parts of the paper or it tends to dirty the entire machine.

Furthermore, it should be taken into account that the dispensers are delicate and require checking and regulation so as not to use excessive doses or—on the contrary—too little doses of glue.

On the contrary, when the glue is released through an overflow slot, over which the end edge of the log or the log itself passes, dirt might spread over the entire machine and even dirty the log, both due to the amount of glue transported by the paper or spills from the overflow slot inadvertently.

Furthermore, it should be taken into account that the gluing units of an end edge of a log are generally particularly complex in terms of manufacturing and in terms of interaction between the various parts that move the log forward, unwind the end edge, or at least a portion thereof, and allow the positioning of the glue thereto.

A particular solution to the problem of feeding the log at the gluing device is according to a proper position described in the European patent application no EP 1440925.

In such solution the described gluing unit comprises, upstream of the glue dispenser, a roller selectively actuatable in rotation upon the passage of he log to be treated.

In particular, such roller is selectively rotated at the same speed at which an upper belt intended for moving the log forward moves forward.

Thus, in such manner the abovementioned roller, cooperating with the upper belt, imparts a rotation to the log, without moving forward, such rotation being aimed at positioning the free end of the final edge according to a particular position.

Once the final edge reaches such position, the abovementioned roller, called “timing roller” for the respective function mentioned above, it is blocked thus moving the “timed” log forward towards the gluing device due to the continuous forward movement of the upper belt.

However, such solution reveals some drawbacks such as, for example, slowing the production cycle.

As a matter of fact, during the abovementioned “timing” of the log, the latter is not moved forward along the machine hence slowing, or even stopping, the other logs being fed.

Additionally, disadvantageously, given that the abovementioned known “timing” roller is, as mentioned, “actuated and blocked” intermittently, it generates—in the machine—high stresses of the mechanical/vibrational type, even quite loud, which can cause damage or breakage of the machine itself over time.

Lastly, such solution is not entirely accurate due to the “on and off” transients of the rotational motion of the “timing” roller which, not being instantaneous and easily controllable processes, can cause errors regarding the positioning of the final edge on the respective log hence jeopardising the subsequent gluing step.

### SUMMARY OF THE INVENTION

Therefore, an object of the present invention is that of identifying a different solution to the abovementioned technical problems regarding proper dispensing and/or positioning the glue, solving problems of the prior art regarding the entire gluing unit of the end edge of the log.

Another object is that of providing a unit adapted to perform the aforementioned task, such unit being particularly simple to operate, even in cases of high production rate, and wherein during the operative step of “timing” the logs the latter are constantly moving forward.

Another object is that of providing a unit wherein the device intended for the operative step of “timing” the logs is actuated continuously and without generating, during operation, high stresses of the mechanical/vibrational type in the unit itself.

Another object is that of providing a unit wherein the device intended for the operative step of “timing” the logs, is not provided with “on and off” transients and it is capable of properly positioning the final edge on the respective log optimising the subsequent gluing step.

These objects according to the present invention are attained by providing and improved gluing unit for an end edge log as described in the claims.

Further characteristics of the invention are outlined by the subsequent claims.

### BRIEF DESCRIPTION OF THE DRAWINGS

Characteristics and advantages of an improved gluing unit for an end edge log according to the present invention shall be clearer from the following exemplifying and non-limiting description, with reference to the attached schematic drawings wherein:

FIG. 1 is a side elevational view, partially in section, of an exemplified. embodiment of the improved gluing unit for an end edge log according to the present invention in a first operative position wherein the log is blocked between an unwinding roller and a forward movement belt;

FIG. 2 is a view similar to that of FIG. 1 in a second operative position with two logs being fed along the path to reach to receive the glue;

FIG. 3 is a view similar to that of FIG. 2 in successive steps of the second operative position, with two logs being fed along the path to reach to receive the glue;

FIG. 4 is a view similar to that shown in FIG. 1 in a third operative position, with three logs being fed along the path to reach the glue-reception zone;

FIG. 5 is a view similar to that of FIG. 4 in successive steps of the third operative position wherein a log is arranged to pick up the glue; and

FIG. 6 is a view similar to that of FIG. 4 and it shows a final part of the third operative position, wherein the previously mentioned log being fed is overturned to receive the glue.

### DETAILED DESCRIPTION

Refining to the Figures, is shown an improved unit 11 for gluing an end edge of a log 14, 14′, 14″ according to the present invention.

References 14, 14′, 14″ shall be subsequently used to indicate both different logs and the same log with respect to respective different operative positions.

In particular log 14 shall refer to a log being fed and in the unwinding step, log 14′ shall refer to a log in the “timing” step, and log 14″ shall refer to a “timed” log just about to receive a gluing substance.

Right from now, it is pointed out that the term “timing” of a log is used to indicate a process that leads the final free edge of the log to be arranged in a determined angular position in a determined position during the forward movement of the log itself inside the machine.

The improved gluing unit for an end edge log subject of the present invention, indicated in its entirety with 11 as mentioned, is arranged in a machine for making logs.

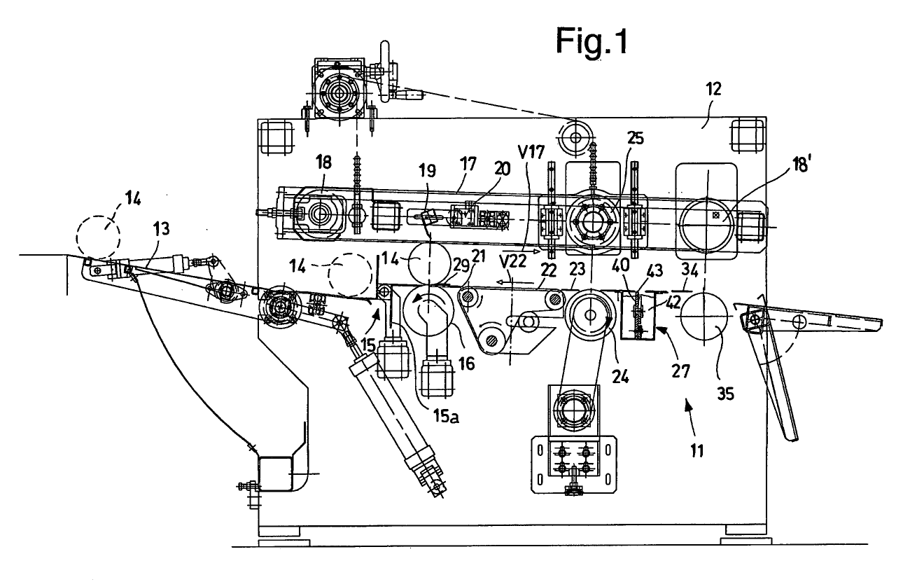

As observable in all. the FIGS. 1-6 this machine generally provides for a bearing structure 12 provided with a feeding surface 13 sloped for feeding logs 14—one after the other, indicated subsequently as mentioned above in the various operative positions also with 14′, 14″ for better understanding—which come from a preceding rereeling machine arranged upstream and not shown.

As shown in FIG. 1, at the end of the tilted feeding plane 13 a rotating sorting device 15 of the star type is provided for, having a series of pockets 15a, which receive the single logs 14 and feeds them one after the other towards the actual gluing unit 11 subject of the invention.

Such gluing unit 11 provides for a first unwinding roller 16, motorised independent and arranged lower with respect to a feeder belt 17. The feeder belt 17 is arranged at the upper part above the gluing unit 11 and it is ring-extended between a pair of end-pulleys 18, 18′.

Arranged at the unwinding roller 16, preferably immediately downstream, are an air nozzle 19, preferably at the upper part, and a sensor 20, preferably at the lower part, such as a photocell such elements cooperating with the belt 17, unwind the final edge 29 of the log 14 according to a preestablished amount.

Such configuration is for example shown in FIG. 1.

Arranged at the exit, i.e. subsequently downstream of the unwinding roller 16 is a first section of the sloped surface 21 which moves the log 14 to a timing unit 22, also motorised in an independent manner.

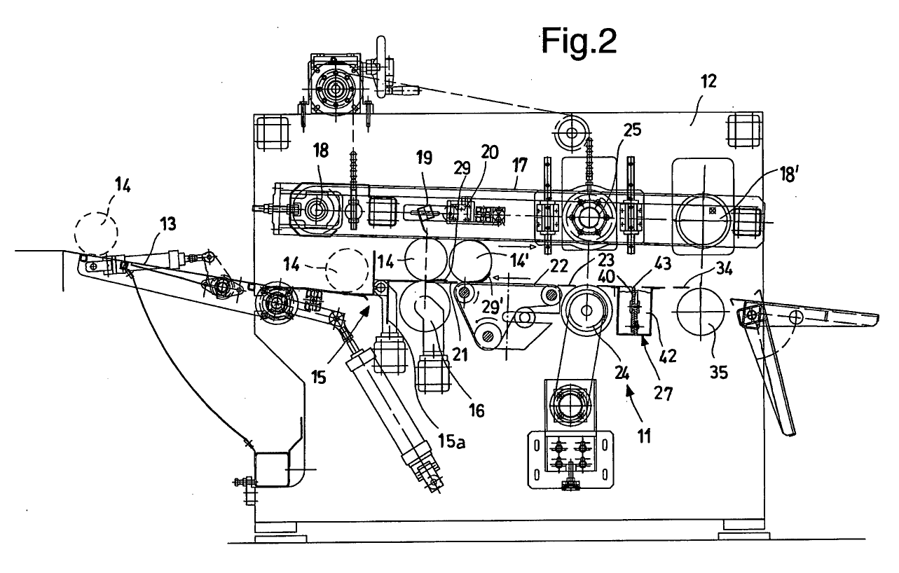

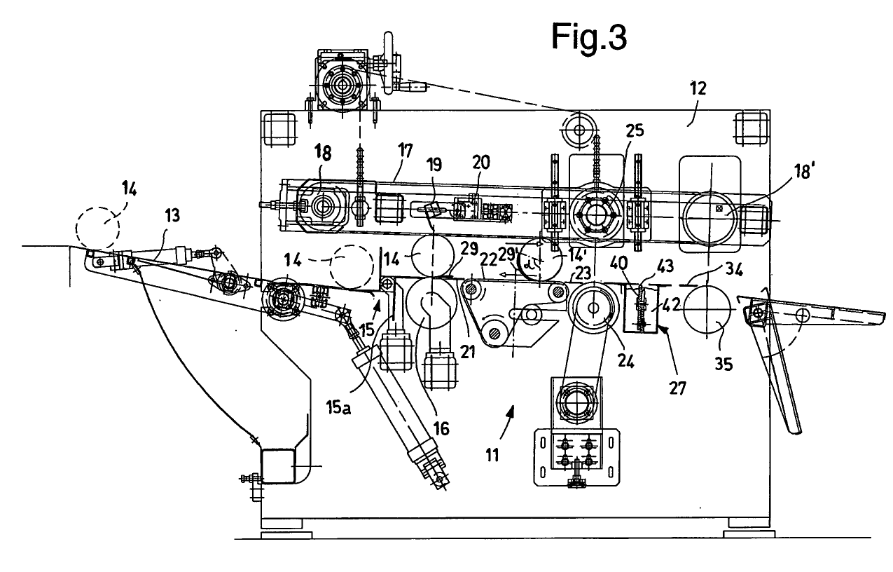

Such timing unit 22, as observable in FIGS. 2 and 3, cooperates with the belt 17 to arrange the final edge 29 of the log 14′ in a pre-established position during the forward movement of the log 14′ itself.

Provided for downstream of this timing unit 22 is a second section of a sloped surface 23 which moves the timed log 14′ towards a third roller 24, referred to as suction roller and also motorised in an independent manner.

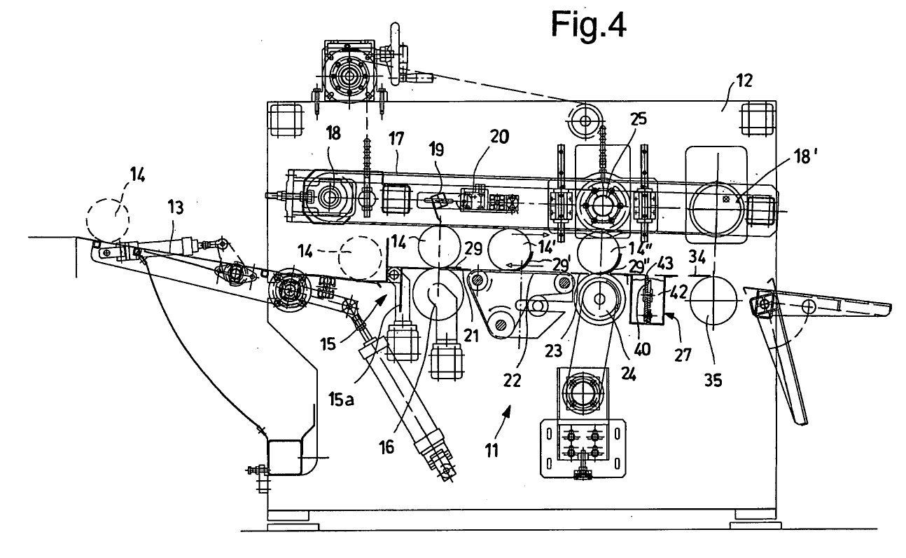

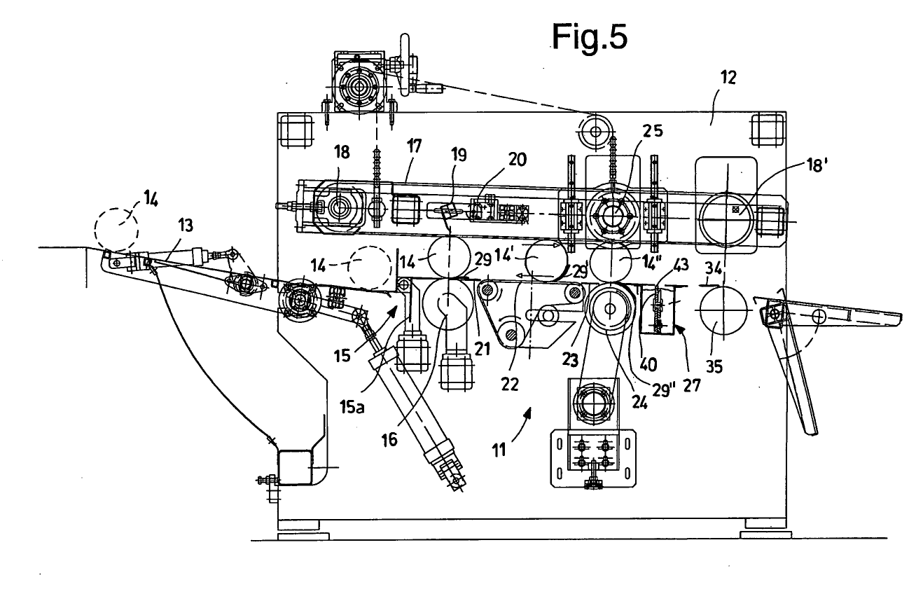

This third suction roller 24 is connected to a vacuum source (not shown) and, for such purpose, and it is provided over its entire external lateral surface with suctioning holes adapted to withhold a preestablished portion of the final edge 29 of the log 14″ as shown in FIGS. 4 and 5.

Furthermore, this third suction roller 24 is arranged aligned below an upper roller 25, also motorised in an independent manner, which is moveable vertically towards and away from the suction roller 24 itself.

Provided for beneath the feeder belt 17 and immediately after the suction roller 24 is any glue dispenser device 27.

In the shown example, this glue dispenser 27 comprises a container 42 holding a gluing substance and a rod element 40 which is capable of cyclically being provided with glue on an upper pointed end 43 thereof.

The abovementioned upper end 43, during or immediately before, the forward moving log 14″ is at the glue dispenser 27, due to a mechanism not shown, performs a raising movement, of the vertical type, and comes into contact with the external surface of the log 14″ in motion.

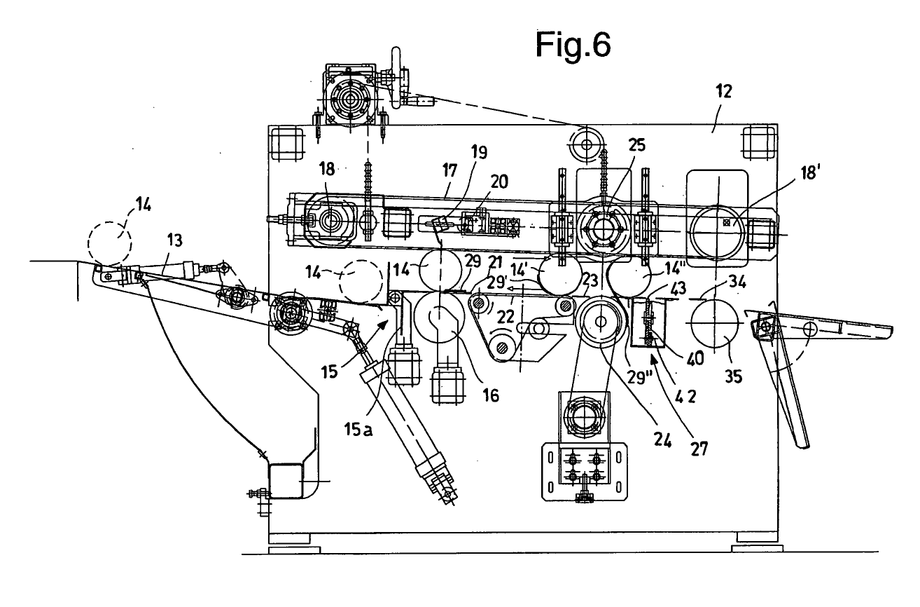

Thus, due to contact, part of the gluing substance held in the container 42 is released onto an external surface of the log 14″ different from the final edge 29 previously withheld by the suction roller 24 as shown in FIG. 6.

Lastly, provided for is an sloping evacuation surface 34 extended above which is the end part of the feeder belt 17, which ensures the constraint between the final end edge 29 of the log 14 and the log or roll itself, securely attaining the glue bond.

In particular the timing unit 22 comprises according to the invention at least one belt or bend element 22, possibly suctioned and/or blown, moveable at a constant speed V22 opposite with respect to the forward movement speed V17 of the feeder belt 17.

Furthermore, according to the invention the abovementioned speed V22 is always lower than the speed V17 of the feederbelt 17.

Advantageously the value of the speed V22 can be set by a user according to the diameter of the logs 14 to be treated, at the beginning of each production cycle by operating on a dedicated motorisation.

In particular such at least one belt or bend element 22 cooperates with the feeder belt 17 and positions the free end of the final edge 29 of the log 14′ in a position arranged according to an angle a with respect to the vertical at the exit of the timing unit 22 itself.

In particular such angle a depends on the diameter of the log 14′, variable factor, and on the length of the second section of sloped surface 23, constant factor, in such a manner that when the log 14″ itself reaches on the suction roller 24 by rolling on the second section of sloped surface 23, the free end of the final edge 29″ is arranged at the zone of contact of the log 14″ with the suction roller 24.

The operation of an improved gluing unit 11 for an end edge log arranged in a machine for the finished making of the log is extremely simple.

The logs 14, wound almost to their final dimension, are fed on the sloped surface 13 coming from a preceding rereeling machine, arranged in the line.

Each single log 14 is arranged in a pocket 15a of the rotating sorting device 15 and it is then fed according to a pre-established succession towards the gluing unit 11 of the present invention.

As a matter of fact, as shown in FIG. 1, the log 14 is arranged on the unwinding roller 16, positioned at the lower part, and it is withheld by the upper feeder belt 17. The unwinding roller 16 rotates in an anticlockwise direction, while the feeder belt 17 moves forward in such a manner to exert a given pressure on the log 14, though rotating it. In such manner, the final edge 29 of the log 14 is moved, by rotating the log 14, to the blowing element 19. This blowing element 19 operates to open the final edge from the rest of the log 14 and the photocell 20 detects whether this opening occurs in a sufficient and proper manner.

According to a particular embodiment such photocell 20 reads the length of the edge 29 when in contact against the first flat section 21.

At this point, i.e. after the photocell 20 had detected that the edge 29 has reached a pre-established length, the unwinding roller 16 stops and the continuous forward movement of the upper feeder belt 17 causes the log 14 to roll on the first section of the sloped surface 21 moving towards the at least one timing belt element 22.

In this second operative position, i.e. during the step of passage between the at least one belt element 22, at the lower part, and the feeder belt 17, at the upper part, the log—indicated in FIG. 2 with 14′ to distinguish the different step performed by the unit 22 with respect to the previous unwinding performed by the roller 16—is moved forward rolling in such a manner that at the end of the at least one belt element 22 the log 14′ has the free end of the final edge 29′ in a pre-selected position.

In other words, as shown in FIG. 3, at the end of the at least one belt element 22 the free end of the final edge 29′ of the log 14′ identifies a given pre-selected angle α with respect to the vertical depending on the diameter of the log 14′ and on the length of the second flat section 23 in such a manner that the log 14″ comes into contact with the suction roller 24 with such free end of the final edge 29″.

Upon setting such position at the final edge 29′ of the log 14′ due to the at least one belt element 22, the timed log 14′ moves on the second flat section 23 towards the suction roller 24 due to the upper feeder belt 17.

Due to such rolling, the timed log 14″ joins with the free end of the final edge 29″ arranged at the zone of contact with the suction roller 24 (also referable to as the six o'clock position of the clock hands in FIG. 4).

The log—indicated with 14″ to distinguish the different step performed by the suction roller 24 with respect to the timing performed beforehand by the at least one belt element 22—is arranged in the aforedescribed condition between the upper roller 25 and the suction roller 24.

At this point, the suction roller 24 is driven to rotate in a clockwise direction and also the upper roller 25 is started to rotate in the clockwise direction. Consequently, the final edge 29″ is unwound to the pre-established amount, as shown in FIG. 5.

Upon termination of this operation, stopping the upper roller 25 determines the forward movement of the log 14″. while the final edge 29″ is withheld by the suction roller 24. In such manner, as observable in FIG. 6, the upper belt 17 drags the log 14″ to roll on the pointed end 43 of the rod element 40 which moves the gluing substance towards the log itself picking it up from the container 42.

Upon acquiring the glue, the final edge 29″ is released by the suction roller 24 and the upper belt 17 causes the rolling of the log 14″ on the sloping evacuation surface 34 in such a manner that the glue remains inside the log between the log itself and the final edge 29″, attaching them mutually.

A roller 35, arranged on the sloping evacuation surface 34, rotates causing the glued part to be transferred to the upper part of the log preventing the soiling of the surface itself.

It is thus understandable how at least on belt element 22 cooperating with the upper belt 17 has the important function of “timing” the position of the final edge 29, i.e. of the free end thereof, depending on the diameter of the log being treated, variable parameter, and on the length of the sloped surface 23, fixed parameter, with the aim of always moving the free end of the final edge 29″ arranged at the zone of contact with the suction roller 24 as shown in FIG. 4.

Advantageously the abovementioned at least one belt element 22 is connected to a variable motor in such a manner to be able to guarantee the respective abovementioned function in presence of any diameter of the log being treated.

This thus allows the unit 11 to glue the log of variable diameter, simply due to the variation—to be performed at the beginning of the respective production cycle—of the speed V22 of the at least one belt element 22.

In this manner a proper positioning of glue on a log to glue the end edge thereto in a quick and accurate manner is performed. Such positioning occurs in rapid succession with several logs being treated simultaneously due to the fact that the timing always occurs with the log moving towards the gluing substance dispenser.

In this manner, the problems indicated in the introduction regarding gluing units known up to date and used in the log manufacturing industry to make rolls of toilet paper, paper for domestic use and the like were solved.

As a matter of fact, given that the log is constantly moving along the machine also during the passage over the at least one timing belt element 22, the production cycle is more efficient eliminating a step wherein, in the known machines, the log did not move forward hence slowing down or requiring interruption of the feeding of the other logs.

Furthermore, advantageously, given that the abovementioned at least one timing belt element 22 is always in motion, it does not cause any, or causes very little, stresses of the mechanical/vibrational type deriving from a possible intermittent starting of the unit 22 itself.

Lastly, given that the at least one timing belt element 22 is always in motion, it does not have “oil and off” transients, non-instantaneous and scarcely controllable events, hence arranging the final edge of the respective log in an extremely accurate manner thus optimising the subsequent gluing step.

The improved gluing unit for an end edge log of the present invention thus conceived is susceptible to various modifications and variants, all falling within the same inventive concept; in addition, all details may be replaced by technically equivalent elements. In practice, the materials used, as well as the dimensions thereof, may vary depending on the technical requirements.

We claim:

1. Improved gluing unit for an end edge of a log arranged in a bearing structure of a machine for making logs, wherein said structure has a sloped surface for feeding logs and at the end of said sloped surface a rotating sorting device provided with a series of pockets for receiving single logs and feeding them towards said gluing unit, said gluing unit comprising—at the upper part—a feeder belt, moving forward at a constant speed in the forward movement direction of said logs and cooperates to evacuate the glued log, and—at the lower part—in succession after said rotating sorting device an unwinding roller, a first section of sloped surface, a timing unit a second section of sloped surface, a suction roller, connected to a vacuum source arranged above which is an upper roller adjustable in height, a glue dispenser device and evacuation surface, further provided for at said unwinding roller being an element for blowing a final edge of said log and a photocell for detecting said final edge, characterised in that said timing unit comprises at least one belt element moveable at constant speed in the opposite direction with respect to said feeder belt, said speed being lower than said speed, said at least one belt element cooperating with said feeder belt and positioning a free end of said final edge of said log in a position arranged according to an angle (α) with respect to the vertical depending on the diameter of said log in such a manner that when said log reaches said suction roller by rolling on said second section of sloped surface said free end of the final edge is arranged at the zone of contact with said suction roller.

2. Gluing unit according to claim 1, characterised in that said suction roller, upon receiving said log in the position with the free end of the final edge thereof arranged at the zone of contact with said suction roller, rotates in a clockwise direction, same case applying to said upper roller, to unwind the final edge by the pre-selected amount.

3. Gluing unit according to claim 2, characterised in that, upon unwinding said pre-selected amount of the final edge, said upper roller is blocked to move said log over said glue dispenser device in cooperation with said at least one feeder belt which cooperates to evacuate the glued log towards said evacuation surface.

4. Gluing unit according to claim 1, characterised in that said at least one feeder belt comprises a first feeder belt upstream of said upper roller and a second feeder belt downstream of said upper roller.

5. Method actuatable through a unit according to claim 1 for the application of glue at an end edge of a log wherein the end edge is detached using air and measured in a predetermined length by means of a photocell at an un unwinding roller, and glue is subsequently applied to the log in order to glue said end edge before the same is wound again on the log, so as to be evacuated, characterised in that after said step wherein the end edge is detached and measured by the log, said log is rolled until it reaches a timing belt element where said log is moved forward rolling at a certain angle (α) until the log is arranged in a pre-established position with the final edge in a pre-selected position depending on the diameter of the log being treated, then the log thus positioned is rolled along a section of sloped surface of pre-established length before being positioned on a suction roller with the final end of the end edge arranged at the zone of contact with said suction roller, before the end edge is unwound for a pre-established length and the log is provided with glue.

6. Method according to claim 5, characterised in that the rotation of said log, when arranged between said timing belt element and said at least one upper feeder belt, is performed in such a manner to position the free end of the final edge offset by a certain angle (α) with respect to its position of arrival in such a manner to arrange said final edge in a preestablished position depending on the diameter of the log.

7. Method according to claim 6, characterised in that said suction roller, upon receiving said log in the position with its free end of the final edge arranged at the zone of contact with said suction roller, is rotated in the clockwise direction, same case applying to said upper roller, to unwind the final edge by the pre-selected amount.

8. Method according to claim 7, characterised in that, upon unwinding said pre-selected amount of the final edge, said upper roller is determined to be blocked to move said log over said glue dispenser device in cooperation with said at least one feeder belt which cooperates to evacuate the glued log towards said evacuation surface.

9. Method according to claim 6, characterised in that the forward movement of said belt element is performed in the direction opposite to the forward movement of said at least one feeder belt, said belt element moving forward at a speed that is constant and lower than the forward movement speed of said at least one feeder belt.
